(19) United States
(12) Patent Application Publication
(10) Pub. No.: US 2022/0181195 A1
(43) Pub. Date: Jun. 9, 2022

(54) WAFER HOLDER FOR GENERATING STABLE BIAS VOLTAGE AND THIN FILM DEPOSITION EQUIPMENT USING THE SAME

(71) Applicant: SKY TECH INC., Hsinchu County (TW)

(72) Inventors: JING-CHENG LIN, Hsinchu County (TW); CHUN-FU WANG, Hsinchu County (TW)

(21) Appl. No.: 17/194,041

(22) Filed: Mar. 5, 2021

(30) Foreign Application Priority Data
Dec. 3, 2020 (TW) 109142706

(51) Int. Cl. H01L 21/687; H01L 21/67; C23C 16/458; C23C 16/02

(52) U.S. Cl. CPC H01L 21/68785; C23C 16/0209; C23C 16/458; H01L 21/67017

(57) ABSTRACT

A wafer holder for generating a stable bias voltage, which mainly includes a holder, a ring member, and a cover ring, wherein a supporting surface of the holder is used to carry at least one wafer, and the ring member is arranged on the holder and located around the supporting surface and the wafer. The ring member includes an outer surface and an inner surface, wherein the inner surface of the ring member covers a part of the side surface of the holder and makes parts of the side surface exposed. When the cover ring is connected to the ring member, a shielding portion of the cover ring will cover the exposed side surface of the holder to avoid a film being formed on the exposed side surface of the holder to facilitate the formation of a uniform and stable bias voltage on the wafer holder.

### TECHNICAL FIELD

The present disclosure relates to a wafer holder for generating stable bias voltage, more particularly, to a wafer holder that has a partially exposed side surface which is shielded with a cover ring, to form a uniform and stable bias voltage on the holder.

### BACKGROUND

Chemical vapor deposition (CVD), physical vapor deposition (PVD), and atomic layer deposition (ALD) are thin film deposition processes that are commonly used in the manufacturing of integrated circuits, light-emitting diodes, and displays.

A deposition equipment is primarily composed of a chamber and a wafer holder, wherein the wafer holder is located in the chamber and is used to hold at least one wafer. Take PVD as an example, a target material is required to be placed in the chamber facing the wafer on the wafer holder. During PVD process, a noble gas and/or reactant gas is transported into the chamber, bias voltage is supplied respectively to the target material and the wafer holder, and the wafer is heated by the wafer holder. The noble gas in the chamber turns into ionized noble gas due to the effect of high voltage electric field, wherein the ionized noble gas is attracted by the bias voltage on the target material and bombards the target material. The target material atoms or particles splashed from the target material are attracted by the bias voltage on the wafer holder and deposit on the surface of the heated wafer to form a thin film on the surface of the wafer.

In specific, the stability of bias voltage and temperature generated by the wafer holder impacts greatly on the quality of thin films deposited on the surface of the wafer, and thus how to make the wafer holder generate stable temperature and bias voltage is an important issue in thin film deposition process.

### SUMMARY

As described in the background, it is often necessary to form a bias voltage on a wafer holder and to heat a wafer on the wafer holder during deposition process, to enhance the quality and uniformity of a thin film deposited on the surface of the wafer. Hence, the present disclosure provides a novel wafer holder that uses a cover ring to shield an exposed side surface of the wafer holder to prevent the deposition of thin film on the exposed side surface of the wafer holder, so as to facilitate the formation of uniform and stable bias voltage on the holder.

An object of the present disclosure is to provide a wafer holder for generating stable bias voltage, mainly including a holder, a ring member, and a cover ring, wherein the holder includes a supporting surface and at least one side surface around/at the periphery of the supporting surface. The supporting surface of the holder is used to support and hold at least one wafer, and the ring member is in contact with or connected to the side surface of the holder and is arranged around or to surround the supporting surface and the wafer.

The ring member includes an inner surface and an outer surface, wherein the inner surface of the ring member is a side surface that is in contact with an opening. The inner surface of the ring member contacts and/or covers a part of the side surface of the holder, wherein a part or all of the side surface of the holder that is not covered by the ring member is exposed. During deposition process, a bias voltage is formed on the supporting surface and the exposed side surface of the holder, such that both the supporting surface and the side surface of the holder can be used to attract plasma.

Moreover, when the ring member is connected to the cover ring, a shielding portion of the cover ring would shield the ring member and/or the exposed side surface of the holder, so as to prevent thin film from depositing on the exposed side surface of the holder. More specifically, when the cover ring is connected to the ring member, the shielding portion of the cover ring is above or leveled with the supporting surface of the holder and effectively shields the exposed side surface of the holder, to drastically reduce the possibility of thin films forming on the exposed side surface of the holder. The wafer holder of the present disclosure is capable of forming bias voltage on the supporting surface and the side surface for a long period of time, and as such the supporting surface and the side surface of the holder attract plasma continually and so thin films are deposited uniformly on the surface of the wafer on the wafer holder.

An object of the present disclosure is to provide a wafer holder for generating stable bias voltage that mainly includes a holder, a ring member, and a cover ring, wherein the holder includes an electrical conductive portion and a heating unit. The electrical conductive portion and the heating unit are in a stacked arrangement, wherein the electrical conductive portion is closer to a side surface of a wafer on the wafer holder than the heating unit is to the side surface of the wafer on the wafer holder. The ring member is connected to the holder, wherein an inner surface of the ring member only covers a side surface of the heating unit and does not cover all of a side surface of the electrical conductive portion, thereby preventing thin films to be formed on the side surface of the electrical conductive portion, which in turn affects the bias voltage formed on the side surface of the electrical conductive portion.

An object of the present disclosure is to provide a wafer holder for generating stable bias voltage that includes a holder, a ring member, and a cover ring, wherein the holder includes an electrical conductive portion, an electrical-insulating and thermal-conductive unit, and a heating unit. The electrical-insulating and thermal-conductive unit is located between the heating unit and the electrical conductive portion for electrically isolating the heating unit and the electrical conductive portion to prevent the heating unit and the electrical conductive portion from becoming conductive to each other, which in turn affects the stability of bias voltage formed on the electrical conductive portion.

In addition, an inner surface of the ring member only covers a side surface of the heating unit and/or a side surface of the electrical-insulating and thermal-conductive unit, not covering all of the side surface of the electrical conductive portion, which facilitates in the formation of bias voltage on the exposed side surface of the electrical conductive portion. A shielding portion of the cover ring is used to shield the ring member and the exposed side surface of the electrical conductive portion to avoid thin films being formed in the exposed side surface of the electrical conductive portion, which in turn affects the bias voltage formed on the side surface of the electrical conductive portion.

To achieve the aforementioned objects, the present disclosure provides a thin film deposition equipment, which includes a chamber, at least one inlet, at least one holder, a heating unit, an electrical conductive portion, a ring member, at least one shielding member, a cover ring, and a driving unit. The chamber includes an accommodating space, and the at least one inlet is disposed on the chamber and fluidly connected to the accommodating space of the chamber for transporting a process gas to the accommodating space. The holder has a supporting surface and at least one side surface. The supporting surface is used to support and hold at least one wafer, and the side surface is disposed at the periphery of the supporting surface. The heating unit and the electrical conductive portion are disposed in the holder, wherein the electrical conductive portion is closer to the supporting surface of the holder than the heating unit is. The ring member is disposed on the holder and around the wafer, and has an inner surface and an outer surface. The inner surface of the ring member covers a side surface of the heating unit, and a part or all of a side surface of the electrical conductive portion is exposed. The shielding member is disposed in the accommodating space of the chamber and has an annular flange at one end of the shielding member. The cover ring is disposed on the annular flange of the shielding member, wherein the cover ring includes an opening and at least one shielding portion extending inwardly and along a radial direction of the opening. The driving unit is used to drive the holder to move relative to the shielding member, wherein the driving unit drives the holder to move toward the shielding member so that the cover ring connects to the ring member and the shielding portion of the cover ring shields the exposed side surface of the electrical conductive portion.

The present disclosure provides another thin film deposition equipment, which includes: a chamber with an accommodating space; at least one inlet disposed on the chamber and fluidly connected to the accommodating space of the chamber for transporting a process gas to the accommodating space; at least one holder having a supporting surface for holding at least one wafer, and a side surface disposed at the periphery of the supporting surface; a ring member disposed on the holder and around/surrounds the wafer, wherein the ring member has an outer surface and an inner surface covering a part of the side surface of the holder, and a part of the side surface of the holder not covered by the inner surface of the ring member is exposed; at least one shielding member disposed in the accommodating space of the chamber, wherein one end of the shielding member has an annular flange; a cover ring disposed on the annular flange of the shielding member, wherein the cover ring includes an opening and at least one shielding portion, wherein the shielding portion extends inwardly and along a radial direction of the opening; and a driving unit for driving the holder to move relative to the shielding member, wherein the driving unit drives the holder to move toward the shielding member to connect the cover ring to the ring member and to shield the exposed side surface of the holder with the shielding portion of the cover ring.

The present disclosure provides a wafer holder, which includes: at least one holder having a supporting surface and at least one side surface, the supporting surface is used to hold at least one wafer and the side surface is located around or is disposed at a periphery of the supporting surface; a heating unit and an electrical conductive portion, disposed in the holder, wherein the electrical conductive portion is closer to the supporting surface of the holder than the heating unit is; a ring member disposed on the holder and located around the wafer, wherein the ring member has an outer surface and an inner surface, the inner surface of the ring member covers a side surface of the heating unit, and a part or all of a side surface of the electrical conductive portion is exposed; and a cover ring having an opening and at least one shielding portion extending inwardly and along a radial direction of the opening, wherein when the cover ring is connected to the ring member, the shielding portion of the cover ring shields the side surface of the holder.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a cross-sectional schematic diagram of a wafer holder for generating stable bias voltage according to an embodiment of the present disclosure;

FIG. 2 is an enlarged view of a wafer holder for generating stable bias voltage according to an embodiment of the present disclosure;

FIG. 3 is an enlarged view of a wafer holder for generating stable bias voltage according to an embodiment of the present disclosure;

FIG. 4 is a cross-sectional schematic diagram of a wafer holder for generating stable bias voltage according to another embodiment of the present disclosure;

FIG. 5 is a cross-sectional schematic diagram of a thin film equipment using a wafer holder according to an embodiment of the present disclosure; and

FIG. 6 is a cross-sectional schematic diagram of a thin film equipment using a wafer holder according to an embodiment of the present disclosure.

### DETAILED DESCRIPTION OF THE PREFERRED EMBODIMENTS

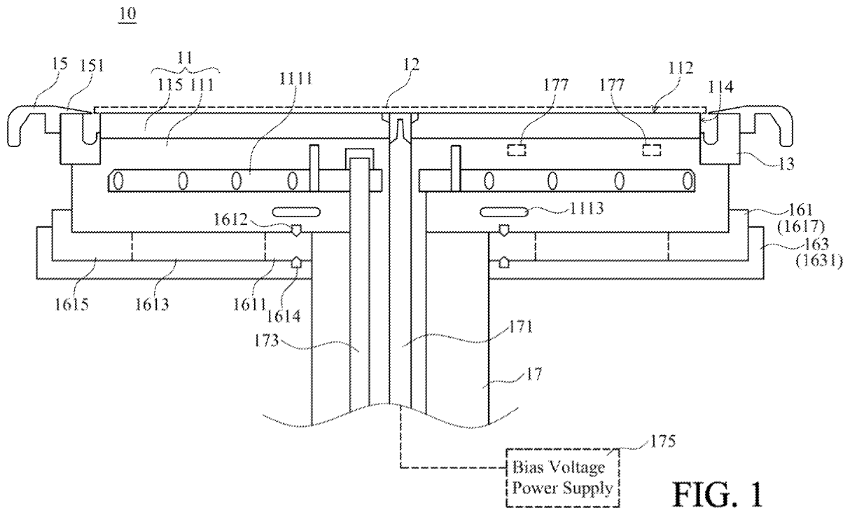

Referring to FIG. 1, a wafer holder 10 for generating stable bias voltage includes at least one holder 11, a ring member 13, and a cover ring 15, wherein the holder 11 has a supporting surface 112 and at least one side surface 114. The supporting surface 112 is used to support or hold at least one wafer 12, and the side surface 114 is disposed at a periphery of the supporting surface, in other words, the side surface 114 is located around and surrounds the supporting surface 112.

In one embodiment, a heating unit 111 and an electrical conductive portion 115 are stacked and disposed in the holder 11, wherein the heating unit 111 and the electrical conductive portion 115 are disc-shaped, and the electrical conductive portion 115 is closer to the supporting surface 112 of the holder 11 than the heating unit 111 is to the supporting surface 112 of the holder 11. When the holder 11 is holding the wafer 12, the electrical conductive portion 115 of the holder 11 is closer to the wafer 12 than the heating unit 11 is.

In one embodiment, the heating unit 111 includes at least one heating coil 1111, wherein the heating coil 1111 is a filament. In operation, an electric current is supplied to the heating coil 1111 and the wafer holder 10 is heated by the heating coil 1111 through electric resistance heating. In another embodiment, the heating coil 1111 is induction coil, and an alternating current is supplied to the heating coil 1111 to generate induced magnetic field by the heating coil 1111 and to heat the wafer holder 12 and the wafer 10 on the wafer holder 12 through the induced magnetic field. Heating the wafer holder 12 with the heating coil 1111 is merely an example of the present disclosure, and does not limit the claim scope of the present disclosure.

The electrical conductive portion 115 is electrically connected to a bias voltage power supply 175, and a bias voltage is formed at the electrical conductive portion 115 through the bias voltage power supply 175 to attract plasma on top of the wafer holder 10 and the wafer 12, for thin films to be deposited on the surface of the wafer 12. The bias voltage power supply 175 can be alternating current power supply or direct current power supply and is used to form an alternating current bias voltage or a direct current bias voltage on the electrical conductive portion 115.

The ring member 13 is disposed on the holder 11 and located around or surrounds the supporting surface 112 of the holder 11 and/or the wafer 12. For example, an annular recess can be disposed on the side surface 114 of the holder 11 near the supporting surface 112, and the ring member 13 is disposed in the annular recess. In one embodiment, the area of the wafer 12 is slightly larger than the supporting surface 112 of the holder 11, and so the side edge of the wafer 12 placed on the supporting surface 112 protrudes from the supporting surface 112 of the holder 11 and shields a part of the ring member 13.

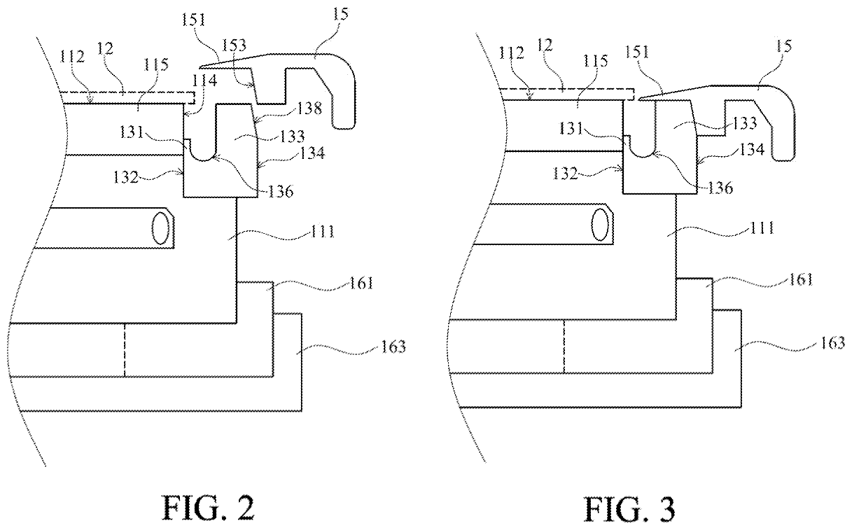

As shown in FIG. 2 and FIG. 3, the ring member 13 includes an opening, an inner surface 132, and an outer surface 134, wherein the inner surface 132 is the side surface of the ring member 13 that connects to the opening. The ring member 13 may be sleeved over the holder 11, wherein the inner surface 132 of the ring member 13 is in contact with and covers a part of the side surface 114 of the holder 11, and other parts of the side surface 114 of the holder 11 not covered by the inner surface 132 of the ring member 13 are exposed. In particular, the height of the inner surface 132 of the ring member 13 is less than the height of the outer surface 114.

In one embodiment, a recess 136 is disposed on an upper surface of the ring member 13 and located between the inner surface 132 and the outer surface 134. A first protrusion 131 is formed between the recess 136 and the inner surface 132 of the ring member 13, and a second protrusion 133 is formed between the recess 136 and the outer surface 134. The height of the second protrusion 133 is higher than the height of the first protrusion 131, in other words, the height of the first protrusion 131 is less than the height of the second protrusion 133. The ring member 13 having the recess 136 is merely an example of the present disclosure and the claim scope of the present disclosure is not limited thereby. More particularly, the main purpose of the present disclosure is for the inner surface 132 and/or the first protrusion 131 of the ring member 13 to not entirely cover the side surface 114 of the holder 11, wherein it is not necessary to dispose the recess 136 in the ring member 13.

In one embodiment, the electrical conductive portion 115 of the holder 11 is closer to the wafer 12 than the heating unit 111 is, and the inner surface 132 and/or the first protrusion 131 of the ring member 13 cover a part or all of a side surface of the heating unit 111 of the holder 11. Moreover, the inner surface 132 and/or the first protrusion 131 of the ring member 13 do not cover the side surface 114 of the electrical conductive portion 115, or only cover a part of the side surface 114 of the electrical conductive portion 115, such that a part or all of the side surface 114 of the electrical conductive portion 115 is exposed.

When the ring member 13 does not entirely cover the side surface 114 of the holder 11 and/or the electrical conductive portion 115, thin film may be formed on the exposed side surface 114 of the holder 11 and/or the electrical conductive portion 115 during deposition process. When the thickness of the thin film formed on the exposed side surface 114 of the holder 11 and/or the electrical conductive portion 115 reaches a certain thickness, or when the exposed side surface 114 of the holder 11 and/or the electrical conductive portion 115 is completely covered by the thin film, bias voltage generated on the side surface 114 of the holder 11 and/or the electrical conductive portion 115 may be discontinued, unstable, or insufficient, and thereby affecting the uniformity of thin film deposited on the surface of the wafer 12. The thickness of the thin film may be, for example, thinner on the outer periphery region than the central region of the wafer, and thus the thin film deposited on the surface of the wafer 12 has an uneven thickness.

On the contrary, if the inner surface 132 and/or the first protrusion 131 of the ring member 13 cover the side surface 114 of the holder 11 and/or the electrical conductive portion 115 entirely, the formation of thin film on the side surface 114 of the holder 11 and/or the electrical conductive portion 115 is prevented. However, when the side surface 114 of the holder 11 and/or the electrical conductive portion 115 is covered by the ring member 13, it is possible that the bias voltage power supply 175 is unable to form bias voltage on the holder 11 and the side surface 114 of the electrical conductive portion 115, or that the holder 11 and the side surface 114 of the electrical conductive portion 115 are incapable of attracting plasma, which are unfavorable in forming a thin film with uniform thickness on the surface of the wafer 12.

To solve the aforementioned issues, the inner surface 132 of the ring member 13 as provided by the present disclosure does not cover the side surface 114 of the holder 11 and/or the electrical conductive portion 115 entirely and so there are exposed regions on the side surface 114 of the holder 11 and/or the electrical conductive portion 115. Therefore, the bias voltage power supply 175 is able to form bias voltage on both the supporting surface 112 and the side surface 114 of the holder 11 and/or the electrical conductive portion 115, and through the side surface 114 and the supporting surface 112 of the holder 11, the plasma is attracted so as to form a uniform thin film on the surface of the wafer 12. In addition, the cover ring 15 of the present disclosure is also used to shield the side surface 114 of the holder 11 and/or the electrical conductive portion 115, so as to prevent the formation of thin film on the exposed side surface 114 of the holder 11 and/or the electrical conductive portion 115, and so the bias voltage power supply 175 is able to continually form bias voltage on the supporting surface 112 and the side surface 114 of the holder 11.

In specific, the cover ring 15 of the present disclosure includes an opening and at least one shielding portion 151, wherein the shielding portion 151 extends or protrudes inwardly in and along a radial direction of the opening, like towards the center point of the opening. When the ring member 13 is connected to the cover ring 15, the shielding portion 151 of the cover ring 15 is above/on top of or leveled with the supporting surface 112 of the holder 11 and shields the ring member 13 and/or the exposed side surface 114 of the holder 11, to reduce the gap between the shielding portion 151 of the cover ring 15 and the supporting surface 112 of the holder 11 and/or the wafer 12, and so the formation of thin film on the side surface 114 of the holder 11 is prevented.

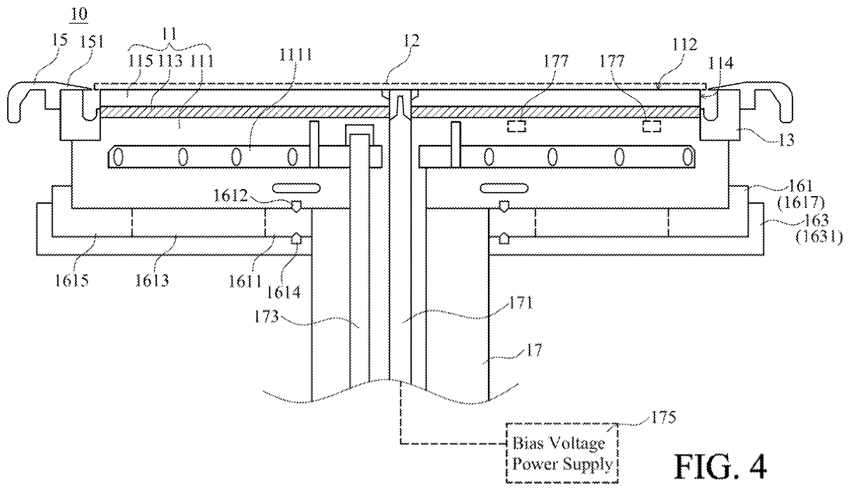

In another embodiment as shown in FIG. 4, the holder 11 includes the heating unit 111, the electrical conductive portion 115, and an electrical-insulating and thermal-conductive portion 113 that are all stacked together. The electrical-insulating and thermal-conductive portion 113 is located between the heating unit 111 and the electrical conductive portion 115 and is used to electrically isolate the heating unit 111 and the electrical conductive portion 115 to prevent the heating unit 111 and the electrical conductive portion 115 from conducting with one another, which in turn affects the stability of the bias voltage on the electrical conductive portion 115. The electrical-insulating and thermal-conductive portion 113 is composed of, literally, material that has thermal-conductive and electrical-insulation properties, like aluminum oxide.

The inner surface 132 and/or the first protrusion 131 of the ring member 13 is mainly used for covering the side surface 114 of the heating unit 111, so as to prevent the formation of thin film on the side surface 114 of the heating unit 111 during deposition process. In one embodiment, the inner surface 132 and/or the first protrusion 131 of the ring member 13 may cover a part or all of the side surface 114 of the electrical-insulating and thermal-conductive portion 113, and may also cover a part of the side surface 114 of the electrical conductive portion 115, such that the electrical conductive portion 115 has some exposed side surface 114 that is not covered by the inner surface 132 and/or the first protrusion 131 of the ring member 13. More particularly, the inner surface 132 and/or the first protrusion 131 of the ring member 13 only needs to cover the side surface 114 of the heating unit 111, and is not necessary to cover the side surface 114 of the electrical-insulating and thermal-conductive portion 113 nor a part of the side surface 114 of the electrical conductive portion 115.

In one embodiment, the wafer holder 10 is connected to a support member 17, wherein the support member 17 includes a first conductive unit 171 disposed therein. The first conductive unit 171 is electrically connected to the electrical conductive portion 115 and the bias voltage power supply 175 and transfers the alternating current bias voltage or the direct current bias voltage supplied by the bias voltage power supply 175 to the electrical conductive portion 115.

Furthermore, at least one second conductive unit 173 may be disposed in the support member 17. The second conductive unit 173 is electrically connected to the heating unit 111, such as connected to the heating coil 1111 of the heating unit 111. In practical application, an alternating current is supplied to the heating coil 1111 through the second conductive unit 173 to increase the temperature of the heating unit 111. In addition, the wafer holder 10 includes at least one temperature sensing unit 177 for measuring the temperatures of the heating unit 111, the electrical conductive portion 115, and/or the wafer holder 10. The first conductive unit 171 and the second conductive unit 173 can be conducting wire or conducting strip.

In one embodiment, the wafer holder 10 includes at least one seat 161 and a base 163, wherein the seat 161 is used to connect the heating unit 111 and the base 163 is used to hold and secure the seat 161.

In specific, the seat 161 may include a plurality of annular connecting elements, like a first annular connecting element 1611, a second annular connecting element 1613, and a third annular connecting element 1615. The support member 17 is located in the opening of the first annular connecting element 1611, wherein the first annular connecting element 1611 is located in the opening of the second annular connecting element 1613 and the second annular connecting element 1613 is located in the opening of the third annular connecting element 1615. In other words, the seat 161 is formed by the first annular connecting element 1611, the second annular connecting element 1613, and the third annular connecting element 1615. The seat 161 having a combination of three connecting elements 1611/1613/1615 is merely an example of the present disclosure and does not limit the claim scope of the present disclosure.

In one embodiment, there is an annular protrusion 1617 at the edge of the seat 161, and the region encircled by the annular protrusion 1617 forms a recess. The heating unit 111 is disposed in the recess of the seat 161, and the annular protrusion 1617 is around and surrounds the heating unit 111.

The base 163 may be a single component and have an annular protrusion 1631 at the edge of the base 163, and the region encircled by the annular protrusion 1631 forms a recess. The seat 161 is disposed in the recess of the base 163 so that the annular protrusion 1631 is around and surrounds the seat 161.

In one embodiment, a first annular sealing element 1612 and a second annular sealing element 1614 are respectively disposed on the upper surface and the lower surface of the innermost first annular connecting element 1611 of the seat 16. The first annular sealing element 1612 and the second annular sealing element 1614 are, for example, O-rings. The first annular sealing element 1612 on the upper surface of the first annular connecting element 1611 is in contact with the heating unit 111, and the second annular sealing element 1614 on the lower surface of the first annular connecting element 1611 is in contact with the base 163. In practical application, the pressure difference between the regions will cause the heating unit 111 and the base 163 to be tightly attached to the seat 161 and/or the first annular connecting element 1611.

Because the first annular sealing element 1612 on the upper surface of the first annular connecting element 1611 is closer to or in direct contact with the heating unit 111, the first annular sealing element 1612 deteriorates after being used for a period of time. To prevent the deterioration of the first annular sealing element 1612, at least one cooling passage 1113 is disposed above the first annular sealing element 1612, through which the heating unit 111 and the first annular sealing element 1612 are isolated/separated, for cooling the first annular sealing element 1612.

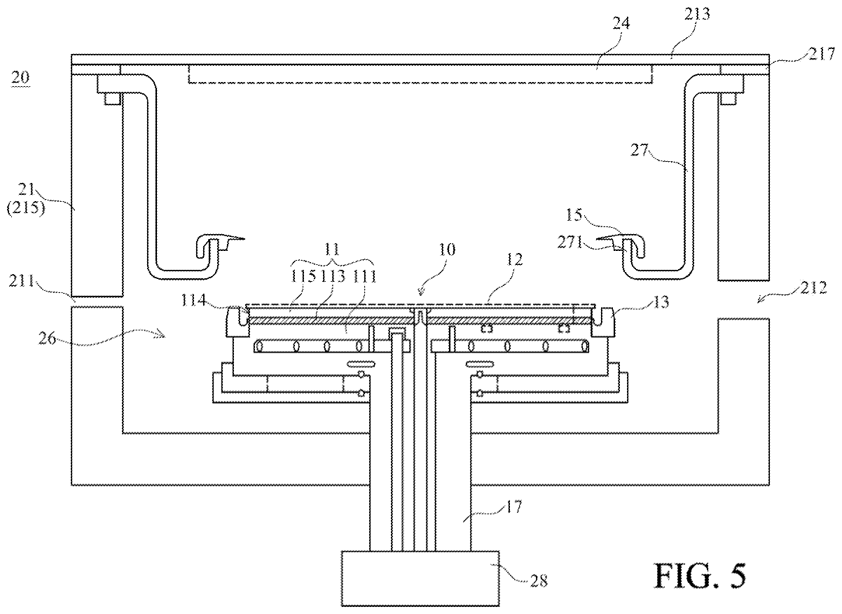

Referring to FIG. 5, a thin film deposition equipment 20 mainly includes at least one wafer holder 10 and a chamber 21, wherein the chamber includes an accommodating space 26. The wafer holder 10 is disposed in the accommodating space 26 and is used to carry/hold at least one wafer 12. The structure of the wafer holder 10 is as shown in FIG. 1 to FIG. 4 and is not described herein.

In one embodiment, the thin film deposition equipment 20 is a PVD apparatus, and a target material 24 is disposed in the chamber 21 facing the wafer holder 10 and/or the wafer 12. In one embodiment, the chamber 21 includes a top board 213 and a lower chamber 215, wherein the top board 213 is connected to the lower chamber 215 through an insulation portion 217, thereby forming the accommodating space 26 between the top board 213 and the lower chamber 215. The target material 24 is disposed on the top board 213 and facing the wafer holder 10 and/or the wafer 12.

The chamber 21 has at least one inlet 211 disposed thereon, wherein the inlet 211 is fluidly connected to the accommodating space 26 of the chamber 21 and is used to transport a process gas into the accommodating space 26 for deposition process. The process gas is a noble gas or a reactant gas. Further, an outlet may be disposed on the chamber 21, such that gas can be extracted from the chamber 21 through the outlet by a pump.

The ring member 13 is disposed on the holder 11 and is around or surrounds the wafer 12. A shielding member 27 is disposed in the accommodating space 26 of the chamber 21 and is located close to and around the wafer holder 10. More specifically, one end of the shielding member 27 is connected to the chamber 21 and the other end forms an opening. In one embodiment, the end of the shielding member 27 not connecting to the chamber 21 has an annular flange 271 formed thereon, wherein the annular flange 271 is located at the periphery of the opening of the shielding member 27. The cover ring 15 may be disposed on the annular flange 271 of the shielding member 27.

The chamber includes a material pass 212, such as a slit valve opening, for transporting the wafer 12. A driving unit 28 is connected to the support member 17 and drives the wafer holder 10 away from the shielding member 27 via the support member 17, as shown in FIG. 5. Then, a mechanical arm takes a wafer 12, passes it through the material pass 212, and place it on the wafer holder 10. The mechanical arm can also take the wafer 12 from the wafer holder 10 and out of the chamber 21 through the material pass 212.

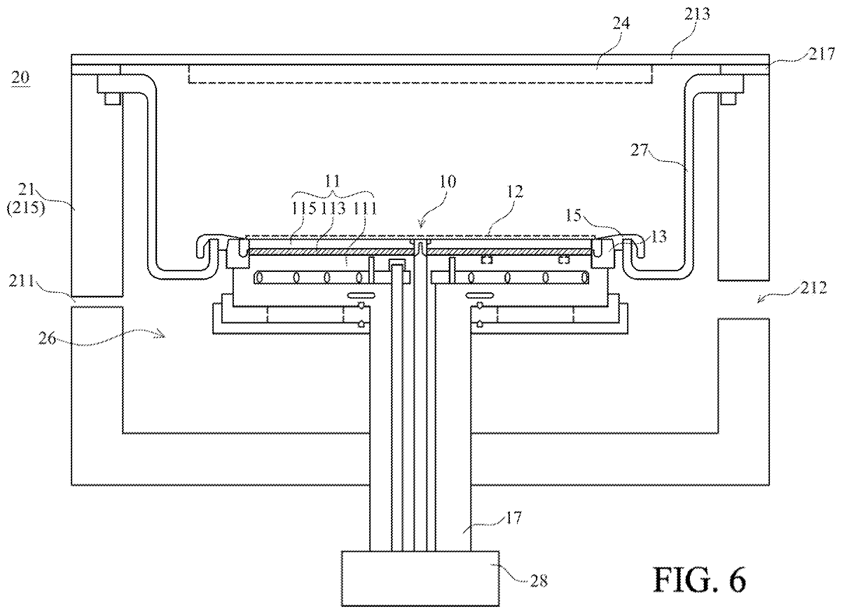

After the mechanical arm placed the wafer 12 on the wafer holder 10, the driving unit drives, via the support member 17, the wafer holder 10 and the wafer 12 thereon in a direction toward the shielding member 27, such that the ring member 13 on the wafer holder 10 contacts the cover ring 15 on the shielding member 27 and the shielding member 27 and the cover ring 15 surrounds the periphery of the wafer 12. The shielding member 27, the cover ring 15, the wafer holder 10, the wafer 12 and/or the ring member 13 divides the accommodating space 26 of the chamber 21 into two sections as shown in FIG. 6.

During the deposition process, the heating unit 111 of the wafer holder 10 heats the wafer 12 and supplies bias voltage to the top board 213 and the electrical conductive portion 215 of the wafer holder 10, respectively. The side surface 114 of the wafer holder 10 and/or the electrical conductive portion 115 is not covered by the ring member 13, and thus bias voltage is formed on the supporting surface 112 and the side surface 114 of the wafer holder 10 and/or the electrical conductive portion 115. Furthermore, the exposed side surface 114 of the wafer holder 10 and/or the electrical conductive portion 115 is shielded by the shielding portion 151 of the cover ring 15, whereby the shielding portion 151 of the cover ring 15 keeps the target material 24 away from the exposed side surface 114 of the wafer holder 10 and/or the electrical conductive portion 115, to prevent thin film from being deposited on the side surface 114 of the wafer holder 10 and/or the electrical conductive portion 115. As such, bias voltage is formed continually on the supporting surface 112 and the side surface 114 of the wafer holder 10 and/or the electrical conductive portion 115.

Due to the high voltage electric field, the noble gas is affected and turns/converted into ionized noble gas. The ionized noble gas is attracted by the bias voltage on the target material 24 and thereby bombards the target material 24. The target material atoms or particles splashed from the target material 24 are attracted by the bias voltage on the wafer holder 10 and thereby deposit on the surface of the wafer 12.

In one embodiment as shown in FIG. 2 and FIG. 3, the ring member 13 includes at least one alignment portion 138 disposed on an external side of the ring member 13. The cover ring includes at least one alignment protruding portion 153 disposed on an external side of the shielding portion 151. When the driving unit 28 drives the holder 11 towards the shielding member 27, the alignment protruding portion 153 of the cover ring 15 comes in contact with the alignment portion 138 of the ring member 13, and the alignment between the cover ring 15 and the ring member 13 is complete.

The embodiments of the present disclosure use PVD deposition equipment as examples, but the PVD deposition equipment does not limit the claim scope of the present disclosure. In practical application, the wafer holder 10 of the present disclosure can also be implemented in CVD equipment or ALD equipment. The wafer holder 10 of the present disclosure is basically suitable for any thin film equipment that requires heating and bias voltage generation on the wafer holder 10.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

1. A thin film deposition equipment comprising:
a chamber, comprising an accommodating space;
at least one inlet, disposed on the chamber and fluidly connected to the accommodating space of the chamber, for transporting a process gas to the accommodating space;
at least one holder, comprising a supporting surface for holding at least one wafer, and at least one side surface disposed at a periphery of the supporting surface;
a heating unit and an electrical conductive portion, disposed in the holder, wherein the electrical conductive portion is closer to the supporting surface of the holder than the heating unit is;
a ring member, disposed on the holder and around the wafer, wherein the ring member comprises an outer surface and an inner surface, the inner surface of the ring member covers a side surface of the heating unit, and a part or all of a side surface of the electrical conductive portion is exposed;
at least one shielding member, disposed in the accommodating space of the chamber, wherein one end of the shielding member has an annular flange;
a cover ring, disposed on the annular flange of the shielding member, wherein the cover ring comprises an opening and at least one shielding portion extending inwardly and along a radial direction of the opening; and
a driving unit for driving the holder to move relative to the shielding member, wherein the driving unit drives the holder to move toward the shielding member to connect the cover ring to the ring member, for the shielding portion of the cover ring to shield the exposed side surface of the electrical conductive portion.

2. The thin film deposition equipment of claim 1, wherein the ring member comprises at least one recess disposed between the inner surface and the outer surface of the ring member, the recess and the inner surface of the ring member form a first protrusion, the recess and the outer surface of the ring member form a second protrusion, and a height of the first protrusion is less than a height of the second protrusion.

3. The thin film deposition equipment of claim 1, wherein when the cover ring is connected to the ring member, the shielding portion of the cover ring is above or leveled with the supporting surface of the holder.

4. The thin film deposition equipment of claim 1, further comprising an electrical-insulating and thermal-conductive portion, disposed between the electrical conductive portion and the heating unit, for electrically isolating the electrical conductive portion and the heating unit.

5. The thin film deposition equipment of claim 1, further comprising a seat for holding the heating unit, and a base for holding the seat, wherein a first annular sealing element is disposed between the seat and the heating unit, and a second annular sealing element is disposed between the seat and the base.

6. The thin film deposition equipment of claim 5, further comprising at least one cooling passage, disposed between the heating unit and the first annular sealing element, for separating the heating unit and the first annular sealing element.

7. The thin film deposition equipment of claim 5, wherein the seat comprises a first annular connecting element and a second annular connecting element sleeved over the first annular connecting element, the first annular sealing element is disposed between the first annular connecting element and the heating unit, and the second annular sealing element is disposed between the first annular connecting element and the base.

8. A thin film deposition equipment comprising:
a chamber, comprising an accommodating space;
at least one inlet, disposed on the chamber and fluidly connected to the accommodating space of the chamber, for transporting a process gas to the accommodating space;
at least one holder, comprising a supporting surface for holding at least one wafer, and at least one side surface disposed at a periphery of the supporting surface;
a ring member, disposed on the holder and around the wafer, wherein the ring member comprises an outer surface and an inner surface, the inner surface of the ring member covers a part of the side surface of the holder, and a part of the side surface of the holder is not covered by the inner surface of the ring member and is exposed;
at least one shielding member, disposed in the accommodating space of the chamber, wherein one end of the shielding member has an annular flange;
a cover ring, disposed on the annular flange of the shielding member, wherein the cover ring comprises an opening and at least one shielding portion extending inwardly and along in a radial direction of the opening; and
a driving unit for driving the holder to move relative to the shielding member, wherein the driving unit drives the holder to move toward the shielding member to connect the cover ring to the ring member, for the shielding portion of the cover ring to shield the exposed side surface of the holder.

9. The thin film deposition equipment of claim 8, wherein when the cover ring is connected to the ring member, the shielding portion of the cover ring is above or leveled with the supporting surface of the holder.

10. The thin film deposition equipment of claim 8, further comprising a seat for holding the heating unit, and a base for holding the seat, wherein a first annular sealing element is disposed between the seat and the heating unit, and a second annular sealing element is disposed between the seat and the base.

11. The thin film deposition equipment of claim 10, further comprising at least one cooling passage, disposed between the heating unit and the first annular sealing element, for separating the heating unit and the first annular sealing element.

12. The thin film deposition equipment of claim 10, wherein the seat comprises a first annular connecting element and a second annular connecting element sleeved over the first annular connecting element, the first annular sealing element is disposed between the first annular connecting element and the heating unit, and the second annular sealing element is disposed between the first annular connecting element and the base.

13. A wafer holder for generating stable bias voltage, comprising:
at least one holder, comprising a supporting surface for holding at least one wafer, and at least one side surface disposed at a periphery of the supporting surface;
a heating unit and an electrical conductive portion, disposed in the holder, wherein the electrical conductive portion is closer to the supporting surface of the holder than the heating unit is;
a ring member, disposed on the holder and around the wafer, wherein the ring member comprises an outer surface and an inner surface, the inner surface of the ring member covers a side surface of the heating unit, and a part or all of a side surface of the electrical conductive portion is exposed; and
a cover ring, comprising an opening and at least one shielding portion extending inwardly and along a radial direction of the opening, wherein when the cover ring is connected to the ring member, the shielding portion of the cover ring shields the side surface of the holder.

14. The wafer holder for generating stable bias voltage of claim 13, wherein the ring member comprises at least one recess disposed between the inner surface and the outer surface of the ring member, the recess and the inner surface of the ring member form a first protrusion, the recess and the outer surface of the ring member form a second protrusion, and a height of the first protrusion is less than a height of the second protrusion.

15. The wafer holder for generating stable bias voltage of claim 13, wherein when the cover ring is connected to the ring member, the shielding portion of the cover ring is above or leveled with the supporting surface of the holder.

16. The wafer holder for generating stable bias voltage of claim 13, further comprising an electrical-insulating and thermal-conductive portion, disposed between the electrical conductive portion and the heating unit, for electrically isolating the electrical conductive portion and the heating unit.

17. The wafer holder for generating stable bias voltage of claim 13, further comprising a seat for holding the heating unit, and a base for holding the seat, wherein a first annular sealing element is disposed between the seat and the heating unit, and a second annular sealing element is disposed between the seat and the base.

18. The wafer holder for generating stable bias voltage of claim 17, further comprising at least one cooling passage, disposed between the heating unit and the first annular sealing element, for separating the heating unit and the first annular sealing element.

19. The wafer holder for generating stable bias voltage of claim 17, wherein the seat comprises a first annular connecting element and a second annular connecting element sleeved over the first annular connecting element, the first annular sealing element is disposed between the first annular connecting element and the heating unit, and the second annular sealing element is disposed between the first annular connecting element and the base.

20. The wafer holder for generating stable bias voltage of claim 13, further comprising at least one temperature sensing unit for measuring a temperature of the wafer holder.
